(19) United States
(12) Patent Application Publication
(10) Pub. No.: US 2022/0293827 A1
(43) Pub. Date: Sep. 15, 2022

(54) LIGHT EMITTING APPARATUS AND MANUFACTURING METHOD THEREOF

(71) Applicant: ASTI GLOBAL INC., TAIWAN, Taichung City (TW)

(72) Inventor: Ying Chieh Chen, Taichung City (TW)

(73) Assignee: ASTI GLOBAL INC., TAIWAN, Taichung City (TW)

(21) Appl. No.: 17/523,931

(22) Filed: Nov. 11, 2021

(30) Foreign Application Priority Data
Mar. 15, 2021 (TW) 110109208

(51) Int. Cl. H01L 33/50; H01L 33/06; H01L 33/00

(52) U.S. Cl. CPC H01L 33/501; H01L 33/06; H01L 33/005

(57) ABSTRACT

A light-emitting apparatus including a circuit substrate, at least one light-emitting device, a light conversion layer, and a light-transmitting layer is provided. The light-emitting device is disposed on the circuit substrate and is electrically connected to the circuit substrate. The light conversion layer covers the light-emitting device. The light-transmitting layer is disposed between the light-emitting device and the light conversion layer. A manufacturing method of a light-emitting apparatus is also provided.

### CROSS-REFERENCE TO RELATED APPLICATION

This application claims the priority benefit of Taiwanese application no. 110109208, filed on Mar. 15, 2021. The entirety of the above-mentioned patent application is hereby incorporated by reference herein and made a part of this specification.

### BACKGROUND

### Technical Field

The disclosure relates to an electronic device and a manufacturing method thereof. Particularly, the disclosure relates to a light-emitting apparatus and a manufacturing method thereof.

### Description of Related Art

Generally speaking, quantum dot films or phosphor films are often formed by vacuum sputtering, vacuum evaporation, or aqueous plating. However, when the above manners of forming are used in a manufacturing method of an electronic device, they may take a relatively great amount of time and/or may be limited by an object to be plated. Taking vacuum sputtering or vacuum evaporation as an example, it is required to place the object to be plated in a cavity, and then vacuum the cavity placed with the object to be plated. In addition, taking aqueous plating as an example, it is required to put the object to be plated in water, which may cause some reliability issues. Moreover, many objects to be plated cannot be in contact with water.

### SUMMARY

The disclosure provides a light-emitting apparatus and a manufacturing method thereof.

A manufacturing method of a light-emitting apparatus of the disclosure includes the following. A circuit substrate is provided. At least one light-emitting device is disposed on a surface of the circuit substrate. A first adhesive layer is formed on the at least one light-emitting device. First light conversion particles are applied on the first adhesive layer to form a first light conversion layer. The first adhesive layer is cured.

A light-emitting apparatus of the disclosure includes a circuit substrate, at least one light-emitting device, a light conversion layer, and a light-transmitting layer. The light-emitting device is disposed on the circuit substrate and is electrically connected to the circuit substrate. The light conversion layer covers the light-emitting device. The light-transmitting layer is disposed between the light-emitting device and the light conversion layer.

Based on the foregoing, in the manufacturing method of a light-emitting apparatus of the disclosure, the light conversion layer can be formed by the light conversion particles under normal temperature and/or normal pressure. Therefore, the manufacturing method of a light-emitting apparatus can be relatively simple, and the light-emitting apparatus can be manufactured relatively quickly.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1I are schematic partial cross-sectional views of part of a manufacturing method of a light-emitting apparatus of the disclosure.

FIG. 2A and FIG. 2B are schematic partial cross-sectional views of part of a manufacturing method of a light-emitting apparatus of the disclosure.

FIG. 3 is a schematic partial cross-sectional view of a light-emitting apparatus of the disclosure.

FIG. 4 is a schematic partial cross-sectional view of a light-emitting apparatus of the disclosure.

FIG. 5A and FIG. 5B are schematic partial cross-sectional views of part of a manufacturing method of a light-emitting apparatus of the disclosure.

FIG. 6 is a schematic partial cross-sectional view of a light-emitting apparatus of the disclosure.

### DESCRIPTION OF THE EMBODIMENTS

Contents of the following embodiments serve for describing instead of limiting. In addition, description of well-known apparatuses, methods, and materials may be omitted so as not to obscure the description of various principles of the disclosure. Directional terms are used herein (e.g., above, below, top, bottom) only with reference to the drawings or in correspondence to conventional terminology, and are not intended to imply absolute orientations. For the sake of clarity in the drawings, dimensions of some elements or film layers may be increased or reduced. Similar components are denoted by the same reference numerals and have similar functions, materials, or manners of formation, and description thereof is omitted. It will be obvious to those ordinarily skilled in the related art that, with the description of the contents of the embodiments and the corresponding drawings, the disclosure may be carried out in other embodiments that depart from the specific details disclosed herein.

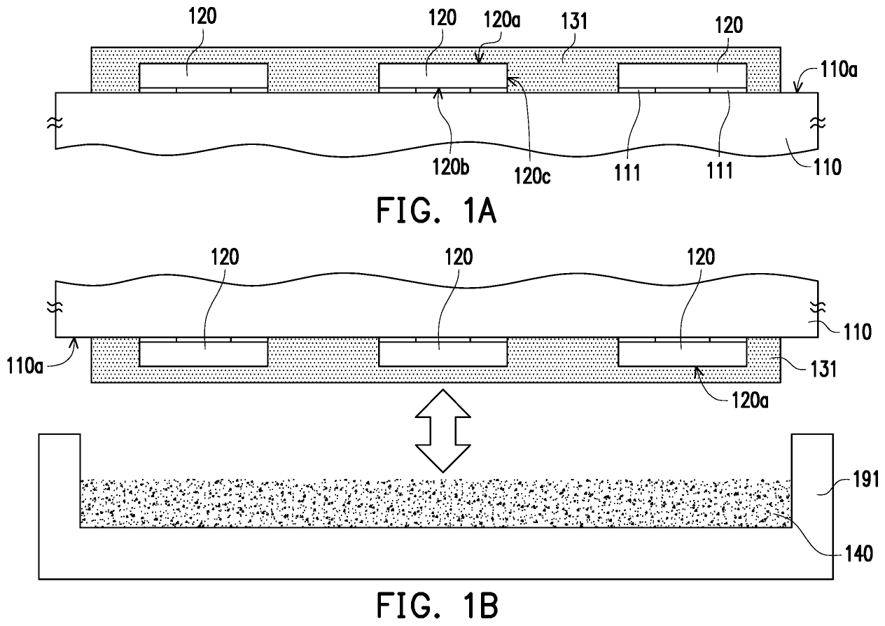

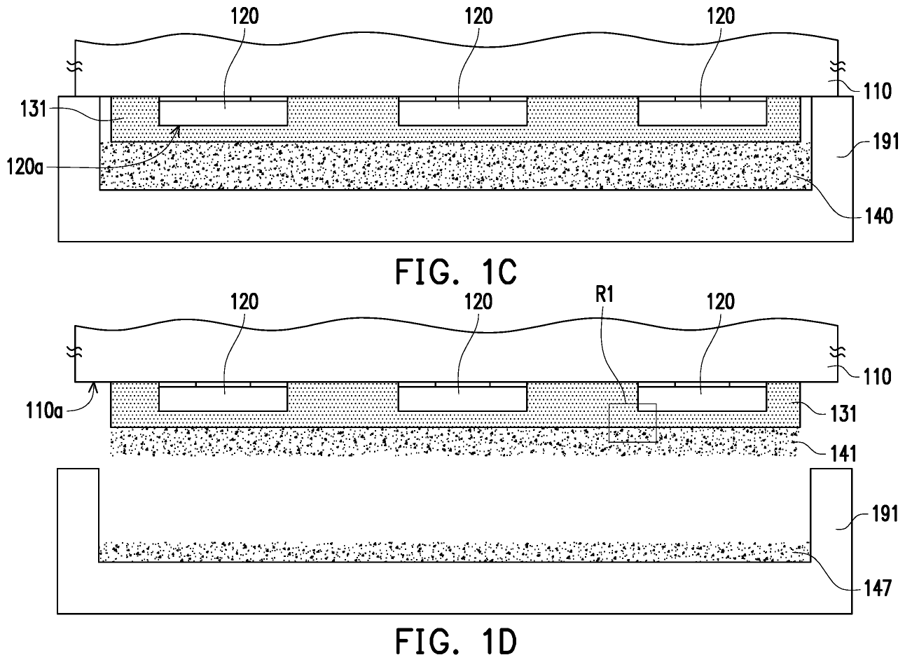

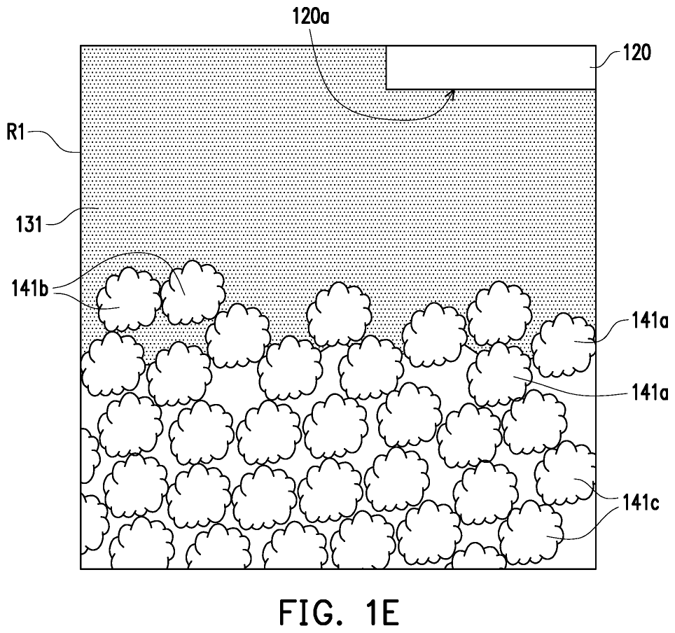

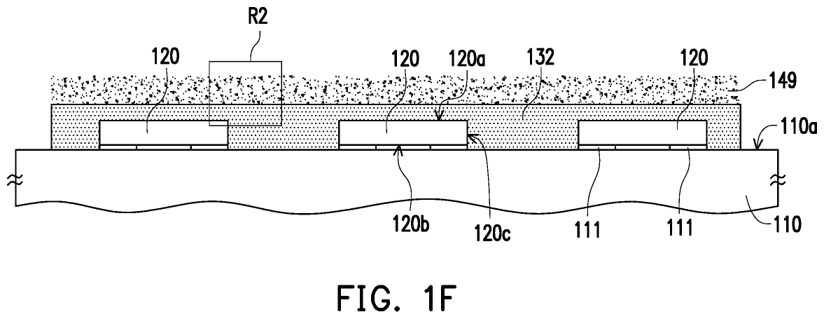

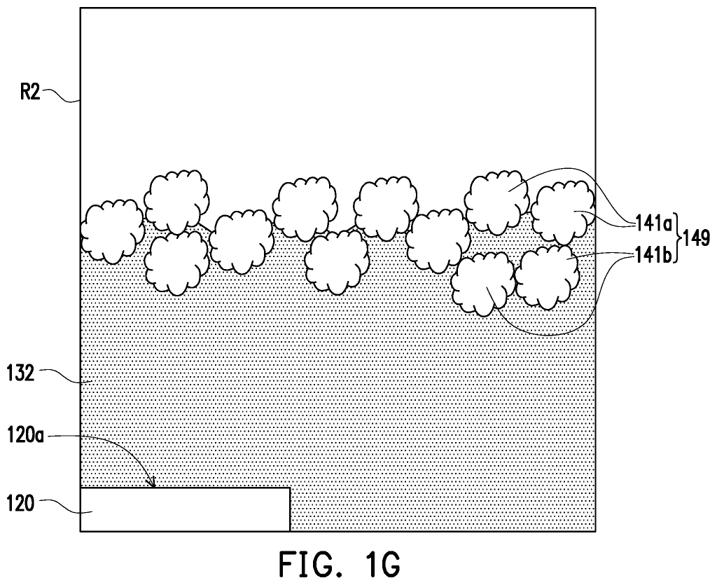

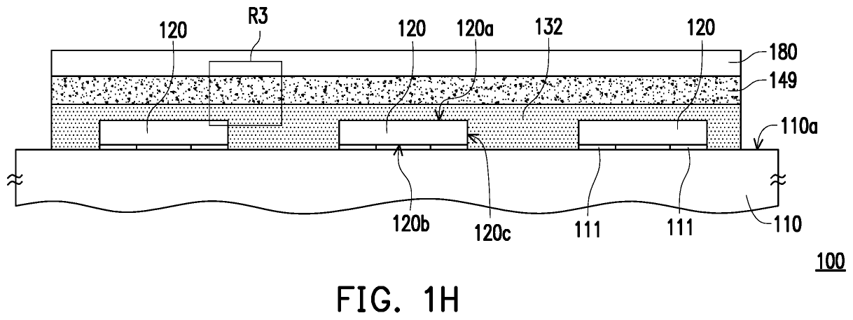

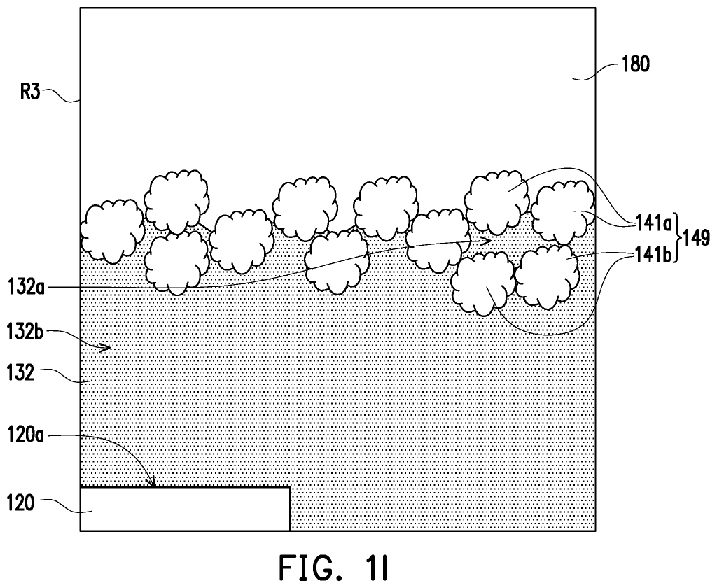

FIG. 1A to FIG. 1I are schematic partial cross-sectional views of part of a manufacturing method of a light-emitting apparatus according to a first embodiment of the disclosure. FIG. 1E may be an enlarged view of area R1 in FIG. 1D. FIG. 1G may be an enlarged view of area R2 in FIG. 1F. FIG. 1I may be an enlarged view of area R3 in FIG. 1H.

With reference to FIG. 1A, a circuit substrate 110 is provided. At least one light-emitting device 120 is disposed on a surface 110a of the circuit substrate 110. FIG. 1A exemplarily shows only three light-emitting devices 120. Nonetheless, the number of light-emitting devices is not limited by the disclosure.

In this embodiment, the circuit substrate 110 may include corresponding devices (e.g., corresponding active devices and/or corresponding driving devices; not shown), corresponding lines (not shown) and/or corresponding connecting pads 111. Nonetheless, the disclosure is not limited thereto. In addition, the layout design of the circuit substrate 110 is not limited by the disclosure.

In an embodiment, the circuit substrate 110 may include a rigid board (for example but not limited to glass board, glass fiber board (e.g., FR4 board)) and/or soft board (for example but not limited to polyimide film or other suitable soft substrate).

In this embodiment, the light-emitting device 120 may be disposed on the connecting pads 111 of the circuit substrate 110 by flip-chip bonding. Nonetheless, the disclosure is not limited thereto.

With further reference to FIG. 1A, a first adhesive layer 131 is formed on the light-emitting device 120. For example, a semi-cured adhesive material may be coated on the surface 110a of the circuit substrate 110 to form the first adhesive layer 131. Nonetheless, the disclosure is not limited thereto.

In this embodiment, the first adhesive layer 131 may be a non-patterned film or layer. Nonetheless, the disclosure is not limited thereto.

In this embodiment, the first adhesive layer 131 covers at least a top surface 120a and a side surface 120c of the light-emitting device 120. In an embodiment, the top surface 120a of the light-emitting device 120 may be the surface farthest away from the circuit substrate 110. A bottom surface 120b of the light-emitting device 120 may be the surface closest to the circuit substrate 110. In addition, the side surface 120c of the light-emitting device 120 may be a surface connecting the top surface 120a and the bottom surface 120b.

With reference to FIG. 1A to FIG. 1G, first light conversion particles 140 (as labeled in FIG. 1B or FIG. 1C) are applied on the first adhesive layer 131 to form a first light conversion layer 149 (as labeled in FIG. 1F or FIG. 1G). Examples of the above step are as follows.

With reference to FIG. 1A to FIG. 1B, the first light conversion particles 140 may be carried in a container 191. The first light conversion particles 140 may include quantum dot (QD) particles, phosphor particles, or other suitable up conversion particles or down conversion particles. Nonetheless, the disclosure is not limited thereto.

In this embodiment, the first light conversion particles 140 may have a particle size between 500 nanometers (nm) and 50 micrometers (μm). In an embodiment, the particle size of the first light conversion particles 140 may be greater than a particle size of particles that are sputtered from high-energy ions (typically from plasma, but not limited thereto) hitting a target.

With reference to FIG. 1B and FIG. 1C, after the first light conversion particles 140 are carried in the container 191, the light-emitting device 120 having the first adhesive layer 131 covered thereon and the container 191 carrying the plurality of first light conversion particles 140 may be brought close to each other to form the first light conversion particles 140 on the first adhesive layer 131.

For example, the structure as shown in FIG. 1A may be flipped upside down, and the top surface 120a of the light-emitting device 120 may be caused to face the first light conversion particles 140 in the container 191. Then, by moving the circuit substrate 110 and/or the container 191, the first adhesive layer 131 covering the light-emitting device 120 and the first light conversion particles 140 in the container 191 are brought close to and further into contact with each other, so that the first light conversion particles 140 may be adhered onto the first adhesive layer 131 by adhesion.

With reference to FIG. 1C, FIG. 1D, and FIG. 1E, after the first light conversion particles 140 are adhered onto the first adhesive layer 131, the circuit substrate 110 and the container 191 may be away from each other by moving the circuit substrate 110 and/or the container 191.

With reference to FIG. 1D, after the circuit substrate 110 and the container 191 are brought away from each other, part of first light conversion particles 147 (part of the first light conversion particles 140) may still remain in the container 191, and another part of first light conversion particles 141 along with the circuit substrate 110 may be away from, and not within, the container 191.

With reference to FIG. 1E, among the first light conversion particles 141 not in the container 191, part of first light conversion particles 141a (part of the first light conversion particles 141) may be partially adhered by the first adhesive layer 131, and part of first light conversion particles 141b (part of the first light conversion particles 141) may be embedded in the first adhesive layer 131 to be completely adhered by the first adhesive layer 131.

In this embodiment, among the first light conversion particles 141 not in the container 191, part of first light conversion particles 141c (part of the first light conversion particles 141) may be not in direct contact with the first adhesive layer 131. For example, a first light conversion particle 141c may be in direct or indirect contact with other first light conversion particles 141 by electrostatic force, Van der Waals force, or other possible manners.

With reference to FIG. 1D, FIG. 1E, FIG. 1F, and FIG. 1G, in this embodiment, the first light conversion particles 141c that are not in direct contact with the first adhesive layer 131 may be removed. For example, at least part of the first light conversion particles 141c may be removed by shaking, vibrating, blowing (e.g., wind blowing), or other suitable manners. In an embodiment, the removed first light conversion particles 141c may be collected by a suitable apparatus to be reused, increasing the utilization rate of materials. The disclosure does not exclude the possibility that some of the first light conversion particles 141c are still adhered onto the first light conversion particles 141a.

With reference to FIG. 1F and FIG. 1G, in this embodiment, at least the first light conversion particles 141a and/or the first light conversion particles 141b covering the light-emitting device 120 may be referred to as or may form the first light conversion layer 149. In other words, the first light conversion layer 149 may include the first light conversion particles 141a and/or the first light conversion particles 141b. Adjacent two of the first light conversion particles 141a and/or the first light conversion particles 141b may be in contact with each other and may also be not in contact with each other. In other words, the first light conversion layer 149 is not limited to a continuous film or layer.

With reference to FIG. 1F and FIG. 1G, in this embodiment, according to the material of the first adhesive layer 131, the first adhesive layer 131 may be cured by light curing, heat curing, or other suitable manners (e.g., standing) to form a first light-transmitting layer 132.

It is worth noting that in the disclosure, it is only required that the first adhesive layer 131 is cured after at least part of the first light conversion particles 140 are brought into contact with the first adhesive layer 131 (e.g., the step as shown in FIG. 1C).

In an embodiment, the structure as shown in FIG. 1F may already be referred to as a light-emitting apparatus. Nonetheless, the disclosure is not limited thereto.

In this embodiment, the first light conversion layer 149 may be formed by the above manners under normal temperature and/or normal pressure. Therefore, the manufacturing method of a light-emitting apparatus can be relatively simple, and the light-emitting apparatus can be manufactured relatively quickly.

With reference to FIG. 1F, FIG. 1G, FIG. 1H, and FIG. 1I, in this embodiment, a protective layer 180 may be formed on the first light conversion layer 149. The protective layer 180 may include an optical-grade insulating film, an inorganic or organic optical film, an insulating film, a hard coat film, an oxygen barrier film having a low oxygen transmission rate (OTR), a water barrier film having a low water vapor transmission rate (WVTR), or a stack or combination of the above film layers. Nonetheless, the disclosure is not limited thereto.

Through the manufacturing method, the manufacturing of a light-emitting apparatus 100 can be substantially completed.

With reference to FIG. 1H and FIG. 1I, the light-emitting apparatus 100 includes the circuit substrate 110, the at least one light-emitting device 120, the first light-transmitting layer 132, and the first light conversion layer 149. The light-emitting device 120 is disposed on the circuit substrate 110 and is electrically connected to the circuit substrate 110. The first light conversion layer 149 covers the light-emitting device 120. The first light-transmitting layer 132 is disposed between the light-emitting device 120 and the first light conversion layer 149.

In this embodiment, a light-emitting apparatus that is the same as or similar to the light-emitting apparatus 100 may be a display (e.g., a light-emitting diode display (LED display)).

In an embodiment, light emitted by the light-emitting device 120 may penetrate the first light-transmitting layer 132. Moreover, the first light conversion layer 149 may absorb the light emitted by the light-emitting device 120 and emit light at other wavelengths.

In this embodiment, the first light conversion layer 149 may include the first light conversion particles 141a and/or the first light conversion particles 141b. Part of the first light conversion particles 141a may be partially in direct contact with the first light-transmitting layer 132. In addition, part of the first light conversion particles 141b may be embedded in the first light-transmitting layer 132 to be completely in direct contact with the first light-transmitting layer 132.

In this embodiment, the first light-transmitting layer 132 may include a first region 132a and a second region 132b. The second region 132b is closer to the light-emitting device 120 than the first region 132a is. The first region 132a of the first light-transmitting layer 132 may directly cover the first light conversion particles 141a and/or the first light conversion particles 141b. The second region 132b of the first light-transmitting layer 132 may not cover the first light conversion particles 141a or the first light conversion particles 141b.

In this embodiment, the light-emitting apparatus 100 may further include the protective layer 180. Part of the first light conversion particles 141a may be partially in direct contact with the protective layer 180. In addition, part of the first light conversion particles 141b may be not in direct contact with the protective layer 180.

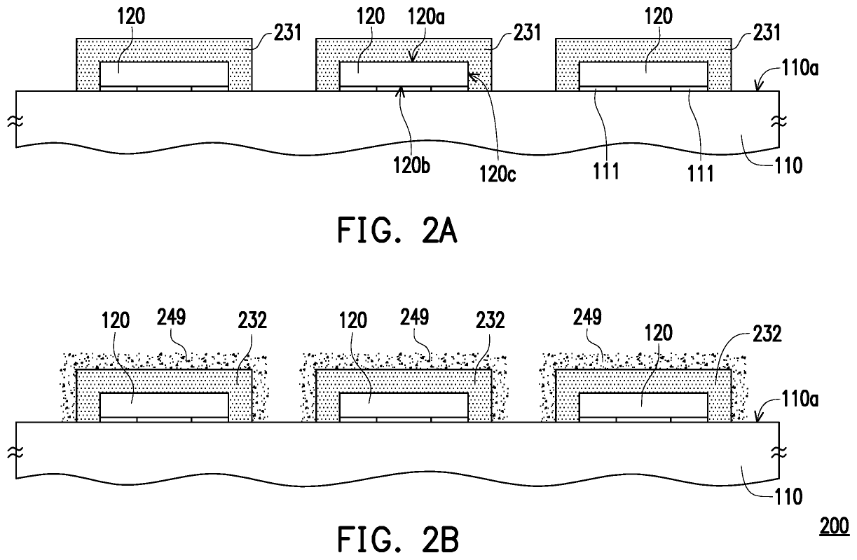

FIG. 2A and FIG. 2B are schematic partial cross-sectional views of part of a manufacturing method of a light-emitting apparatus according to a second embodiment of the disclosure. A manufacturing method of a light-emitting apparatus 200 of this embodiment is similar to the manufacturing method of the light-emitting apparatus 100 of the first embodiment.

With reference to FIG. 2A, a first adhesive layer 231 is formed on the light-emitting device 120.

In this embodiment, the first adhesive layer 231 may be a patterned film or layer. For example, by spraying, dispensing, or ink-jet printing (IJP) together with a mask, the first adhesive layer 231 may be caused to cover at least the top surface 120a and the side surface 120c of the light-emitting device 120.

After that, a first light-transmitting layer 232 may be formed by curing the first adhesive layer 231 in the same or similar manner as shown/described in FIG. 1B to FIG. 1F and FIG. 1G to form the light-emitting apparatus 100 as shown in FIG. 2B.

With reference to FIG. 2B, the light-emitting apparatus 100 includes the circuit substrate 110, the at least one light-emitting device 120, a first light conversion layer 249, and the first light-transmitting layer 232. The first light-transmitting layer 232 is disposed between the light-emitting device 120 and the first light conversion layer 249. The first light conversion layer 249 covers the top surface 120a and the side surface 120c of the light-emitting device 120.

In this embodiment, part of the first light conversion layer 249 may be located between two adjacent light-emitting devices 120.

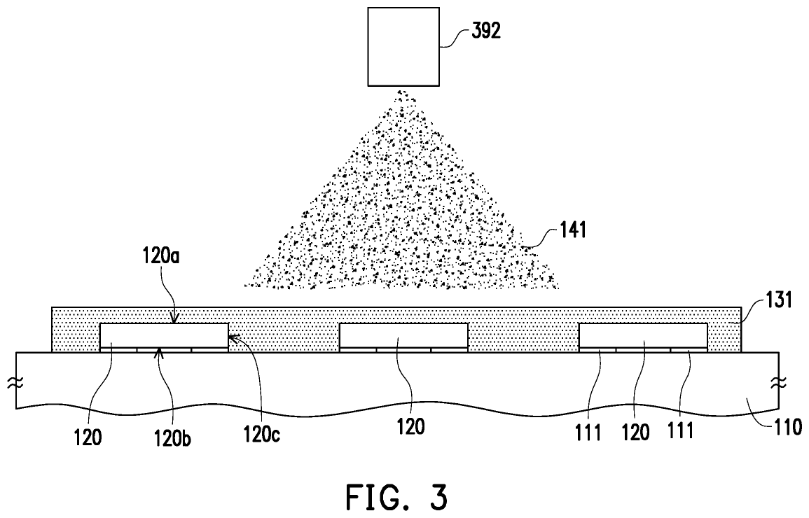

FIG. 3 is a schematic partial cross-sectional view of a light-emitting apparatus according to a third embodiment of the disclosure. The manufacturing method of the light-emitting apparatus (not directly labeled) of this embodiment is similar to the manufacturing method of the light-emitting apparatus 100 of the first embodiment. For example, FIG. 3 is a schematic partial cross-sectional view of the manufacturing method of a light-emitting apparatus following the step of FIG. 1A.

With reference to FIG. 3, in this embodiment, the first light conversion particles 141 may be formed on the first adhesive layer 131 by spreading by using, for example, a sprayer (for example but not limited to a powder sprayer) 392.

The light-emitting apparatus (not directly labeled) formed by the above method may be the same as or similar to the light-emitting apparatus 100 of the first embodiment, and will thus not be repeatedly described herein.

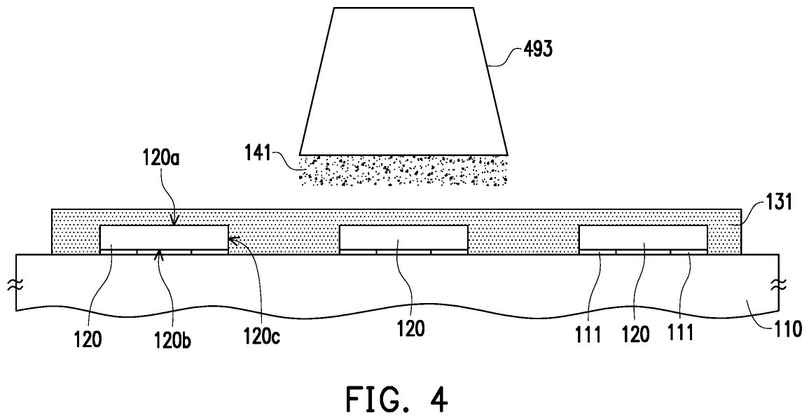

FIG. 4 is a schematic partial cross-sectional view of a light-emitting apparatus according to a fourth embodiment of the disclosure. The manufacturing method of the light-emitting apparatus (not directly labeled) of this embodiment is similar to the manufacturing method of the light-emitting apparatus 100 of the first embodiment. For example, FIG. 4 is a schematic partial cross-sectional view of the manufacturing method of a light-emitting apparatus following the step of FIG. 1A.

With reference to FIG. 4, in this embodiment, the first light conversion particles 141 may be formed on the first adhesive layer 131 by pressing by using, for example, a stamper (for example but not limited to a powder stamper) 493.

The light-emitting apparatus (not directly labeled) formed by the above method may be the same as or similar to the light-emitting apparatus 100 of the first embodiment, and will thus not be repeatedly described herein.

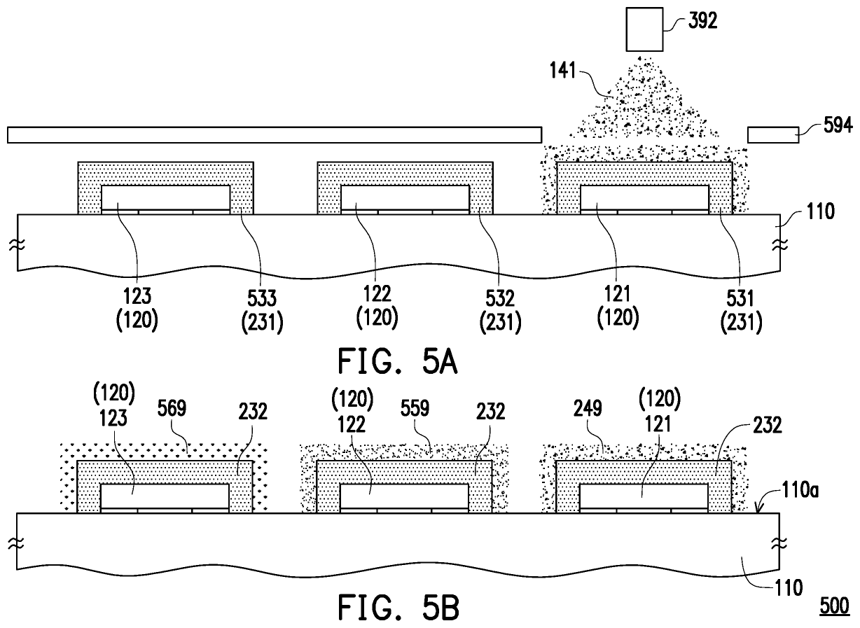

FIG. 5A and FIG. 5B are schematic partial cross-sectional views of part of a manufacturing method of a light-emitting apparatus according to a fifth embodiment of the disclosure. A manufacturing method of a light-emitting apparatus 500 of the embodiment is similar to the manufacturing method of the light-emitting apparatus 200 of the second embodiment or the manufacturing method of the light-emitting apparatus (not directly labeled) of the third embodiment. For example, FIG. 5A is a schematic partial cross-sectional view of the manufacturing method of a light-emitting apparatus following the step of FIG. 2A.

With reference to FIG. 5A to FIG. 5B, in this embodiment, the first light conversion particles 141 may be formed on a first adhesive layer 531 (i.e., part of the first adhesive layer 231) corresponding to a light-emitting device 121 (i.e., at least one of the light-emitting devices 120) by spreading by using, for example, the sprayer 392 and a corresponding mask 594 to form the first light conversion layer 249.

In this embodiment, in the same or similar manner, a second light conversion layer 559 may be formed on a first adhesive layer 532 (i.e., another part of the first adhesive layer 231) corresponding to another light-emitting device 122 (i.e., at least another one of the light-emitting devices 120); and/or a third light conversion layer 569 may be formed on a first adhesive layer 533 (i.e., still another part of the first adhesive layer 231) corresponding to still another light-emitting device 123 (i.e., at least still another of the light-emitting devices 120).

In this embodiment, the light-emitting device 121, the light-emitting device 122, and/or the light-emitting device 123 may emit light of the same color; and/or the first light conversion layer 249, the second light conversion layer 559, and/or the third light conversion layer 569 may have the same material or composition or have different materials or compositions. Nonetheless, the disclosure is not limited thereto.

In an embodiment, by a plurality of light conversion layers having different materials or compositions, the light-emitting apparatus 500 may emit light of different colors in different areas.

In an embodiment not shown, the first light conversion layer 249, the second light conversion layer 559, and/or the third light conversion layer 569 may be formed by stamping.

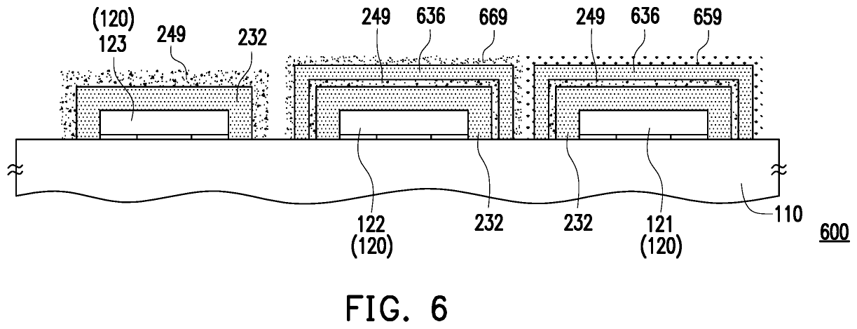

FIG. 6 is a schematic partial cross-sectional view of a light-emitting apparatus according to a sixth embodiment of the disclosure. A manufacturing method of a light-emitting apparatus 600 of this embodiment is similar to the manufacturing method of the light-emitting apparatus 200 of the second embodiment or the manufacturing method of the light-emitting apparatus 500 of the fifth embodiment.

With reference to FIG. 6, in this embodiment, the light-emitting apparatus 600 includes the circuit substrate 110, the light-emitting device 120, the first light-transmitting layer 232, the first light conversion layer 249, a second light-transmitting layer 636, and a second light conversion layer 659. The second light conversion layer 659 covers the first light conversion layer 249. The second light-transmitting layer 636 is disposed between the first light conversion layer 249 and the second light conversion layer 659.

In an embodiment, the second light-transmitting layer 636 and the first light-transmitting layer 232 may have the same or similar material, composition, or manner of formation. For example, a second adhesive layer (not shown) may be formed on the corresponding first light conversion layer 249. Moreover, the second adhesive layer may be cured to form the second light-transmitting layer 636.

In an embodiment, the second light conversion layer 659 and the first light conversion layer 249 may have the same or similar manner of formation. For example, second light conversion particles (not shown) may be applied on the corresponding second adhesive layer (not shown). The second light conversion particles that are in directly contact with the second adhesive layer may be referred to as or form the second light conversion layer 659.

In this embodiment, the first light conversion layer 249 and the second light conversion layer 659 may have the same material or composition or have different materials or compositions. Nonetheless, the disclosure is not limited thereto.

In this embodiment, the light-emitting apparatus 600 may further include a third light conversion layer 669. The third light conversion layer 669 covers the first light conversion layer 249. The second light-transmitting layer 636 is disposed between the first light conversion layer 249 and the third light conversion layer 669.

In this embodiment, the second light conversion layer 659 and the third light conversion layer 669 may have the same material, composition, or manner of formation or have different materials, compositions, or manners of formation. Nonetheless, the disclosure is not limited thereto.

In this embodiment, the second light conversion layer 659 may correspond to the light-emitting device 121, and the third light conversion layer 669 may correspond to the another light-emitting device 122. Nonetheless, the disclosure is not limited thereto.

In summary of the foregoing, in the manufacturing method of a light-emitting apparatus of the disclosure, the light conversion layer can be formed by the light conversion particles under normal temperature and/or normal pressure. Therefore, the manufacturing method of a light-emitting apparatus can be relatively simple, and the light-emitting apparatus can be manufactured relatively quickly.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A manufacturing method of a light-emitting apparatus, comprising:
providing a circuit substrate, wherein at least one light-emitting device is disposed on a surface of the circuit substrate;
forming a first adhesive layer on the at least one light-emitting device;
applying first light conversion particles on the first adhesive layer to form a first light conversion layer; and
curing the first adhesive layer.

2. The manufacturing method as described in claim 1, wherein the first light conversion particles have a particle size between 500 nm and 50 μm.

3. The manufacturing method as described in claim 1, wherein forming the first light conversion particles on the first adhesive layer comprises:
forming the first light conversion particles on the first adhesive layer by spreading or pressing.

4. The manufacturing method as described in claim 1, wherein applying the first light conversion particles on the first adhesive layer comprises:
bringing the at least one light-emitting device having the first adhesive layer covered thereon and a container carrying the first light conversion particles close to each other to form the first light conversion particles on the first adhesive layer.

5. The manufacturing method as described in claim 1, further comprising:
removing a part of the first light conversion particles not in direct contact with the first adhesive layer after applying the first light conversion particles on the first adhesive layer.

6. The manufacturing method as described in claim 1, further comprising:
forming a protective layer on the first light conversion layer.

7. The manufacturing method as described in claim 1, further comprising:
forming a second adhesive layer on the first light conversion layer;
applying second light conversion particles on the second adhesive layer; and
curing the second adhesive layer.

8. A light-emitting apparatus, comprising:
a circuit substrate;
at least one light-emitting device being disposed on the circuit substrate and electrically connected to the circuit substrate;
a light conversion layer covering the at least one light-emitting device; and
a light-transmitting layer disposed between the at least one light-emitting device and the light conversion layer.

9. The light-emitting apparatus as described in claim 8, wherein the light conversion layer comprises quantum dot particles.

10. The light-emitting apparatus as described in claim 8, wherein the light conversion layer comprises phosphor particles.

11. The light-emitting apparatus as described in claim 8, wherein the light-transmitting layer is obtained by curing an adhesive material.

12. The light-emitting apparatus as described in claim 11, wherein the light conversion layer is adhered onto and covers the at least one light-emitting device by the adhesive material.

13. The light-emitting apparatus as described in claim 8, wherein the light-emitting apparatus is a display.
